(19) United States
(12) Patent Application Publication
(10) Pub. No.: US 2004/0083604 A1
(43) Pub. Date: May 6, 2004

(54) Pin lamination method that may eliminate pits and dents formed in a multi-layer printed wiring board and the ply-up device thereof

(76) Inventor: Tse Ying Liu, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/695,983

(22) Filed: Oct. 30, 2003

Related U.S. Application Data
(62) Division of application No. 10/006,125, filed on Dec. 10, 2001.

(51) Int. Cl. C09J 1/00; H05K 3/36

(52) U.S. Cl. 29/830; 156/182; 156/228; 29/837

(57) ABSTRACT

A pin lamination method that may eliminate pits and dents formed in a multi-layer printed wiring board, includes the steps of: (a) preparing steel plates and coppers in a clean working room, and preparing prepregs and cores in a working room; (b) laminating a first copper having a shiny surface facing upward, a steel plate, and a second copper having a shiny surface facing downward, thereby forming a sandwiched lamination board, with the steel plate sandwiched between the first and second coppers, wherein the shiny surface of each of the first and second coppers is directed toward the steel plate; and (c) conveying the sandwiched lamination board to the working room, and laminating the sandwiched lamination board, the prepregs, and the cores serially, thereby forming a multi-layer board.

### BACKGROUND OF THE INVENTION

1. Field of the Invention

The present invention relates to a pin lamination method that may eliminate pits and dents formed in a multi-layer printed wiring board and the ply-up device thereof, wherein phenomenon of pits and dents will be wholly eliminated, thereby enhancing the quality of the multi-layer board, and thereby enhancing the quality of the product of the multi-layer printed wiring board.

2. Description of the Related Art

Usually, a multi-layer printed wiring board needs to be treated by a lamination process during fabrication. The lamination process may laminate at least one core, multiple prepregs and coppers (the coppers may function as outer layers) layer by layer. After the lamination process is finished, the laminated layers may be treated by a heat press process, thereby making a multi-layer board. Then, the coppers at the outer layers of the multi-layer board may be printed with circuit patterns, thereby making the multi-layer printed wiring board. The lamination process may use a pin lamination method to laminate the cores, prepregs, and coppers.

A conventional pin lamination method in accordance with the prior art shown in FIG. 1 may be used to make multiple multi-layer boards “A”.

The multiple multi-layer boards “A” are mounted between two mold plates 11, multiple buffer plates 12, and multiple steel plates 16. Each of multiple multi-layer boards “A” includes at least one core (preferably two cores) 15, multiple prepregs 14, and multiple coppers 13 each pre-fabricated with pin holes aligned with the pins 17 on the mold plates 11, so that the cores 15, the prepregs 14, and the coppers 13 may be laminated layer by layer, and may be treated by a heat press process, thereby making the multiple multi-layer boards “A”.

However, the prepreg 14 is often made of epoxy resin whose tiny fragment and powder are easily adhered on the shiny surface of the copper 13, so that the copper 13 located on the outer surface of the multi-layer board is easily formed with pits and dents, thereby influencing the quality of the multi-layer board “A”, and thereby influencing the quality of the product of the multi-layer printed wiring board.

### SUMMARY OF THE INVENTION

The present invention has arisen to mitigate and/or obviate the disadvantage of the conventional pin lamination method.

The primary objective of the present invention is to provide a pin lamination method that may eliminate pits and dents formed in a multi-layer printed wiring board and the ply-up device thereof, wherein phenomenon of pits and dents will be eliminated, thereby enhancing the quality of the multi-layer board, and thereby enhancing the quality of the product of the multi-layer printed wiring board.

In accordance with a first aspect of the present invention, there is provided a pin lamination method that may eliminate pits and dents formed in a multi-layer printed wiring board, comprising the steps of:

(a) preparing a plurality of steel plates and coppers in a clean working room, and a plurality of prepregs and cores in a working room;

(b) serially laminating a first one of the coppers having a shiny surface facing upward, one of the steel plates, and a second one of the coppers having a shiny surface facing downward on a ply-up device, thereby forming a sandwiched lamination board, with the steel plate sandwiched between the first and second coppers, wherein the shiny surface of each of the first and second coppers is directed toward the steel plate; and

(c) conveying the sandwiched lamination board to the working room, and laminating the sandwiched lamination board, the prepregs, and the cores serially, thereby forming a multi-layer board.

In accordance with a second aspect of the present invention, there is provided a ply-up device for performing the pin lamination method that may eliminate pits and dents formed in a multi-layer printed wiring board, wherein the ply-up device includes a work table, a lift rod, an inclined board, a base steel plate, and a ply-up plate, wherein:

the lift rod has a first end pivoted on a first side of the work table, and a second end pivoted with a first end of the inclined board which has a second end pivoted on a second side of the work table, the lift rod may be lifted and lowered for adjusting the inclined angle of the inclined board;

the base steel plate is secured on the inclined board; and

the ply-up plate is secured on the base steel plate.

Further benefits and advantages of the present invention will become apparent after a careful reading of the detailed description with appropriate reference to the accompanying drawings.

### BRIEF DESCRIPTION OF THE DRAWINGS

FIG. 1 is a schematic view of a conventional pin lamination method for a multi-layer printed wiring board in accordance with the prior art;

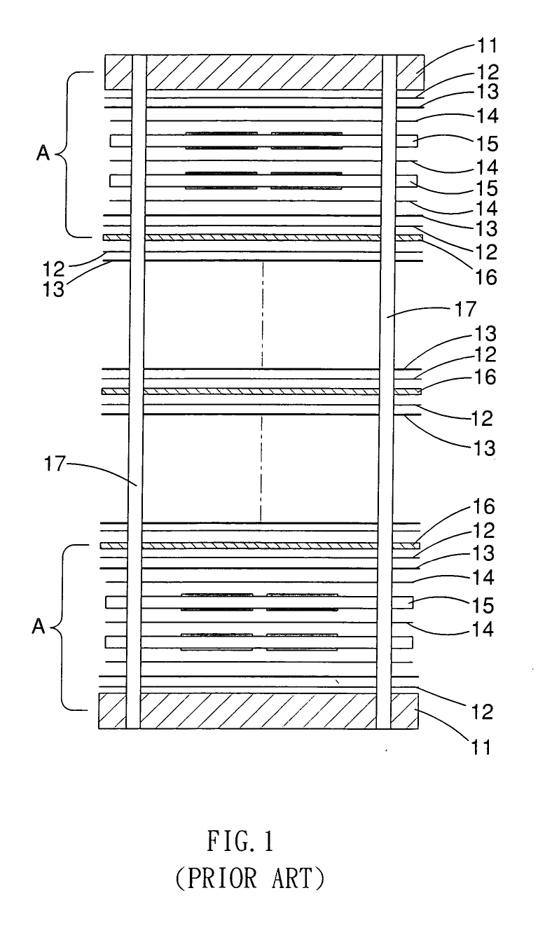

FIG. 2 is a schematic view of a pin lamination method that may eliminate pits and dents formed in a multi-layer printed wiring board in accordance with a preferred embodiment of the present invention;

FIG. 3 is a perspective view of a ply-up device in accordance with a preferred embodiment of the present invention;

FIG. 4 is a side plan view of the ply-up device as shown in FIG. 3;

FIG. 5 is a side plan cross-sectional assembly view of a sandwiched lamination board in accordance with a preferred embodiment of the present invention; and

FIG. 6 is a cross-sectional view of a multi-layer board in accordance with a preferred embodiment of the present invention.

### DETAILED DESCRIPTION OF THE INVENTION

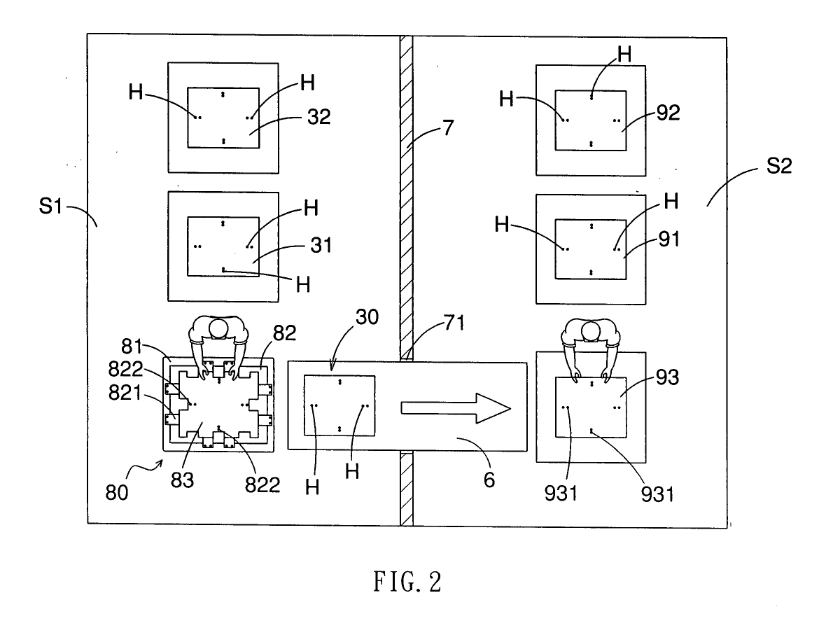

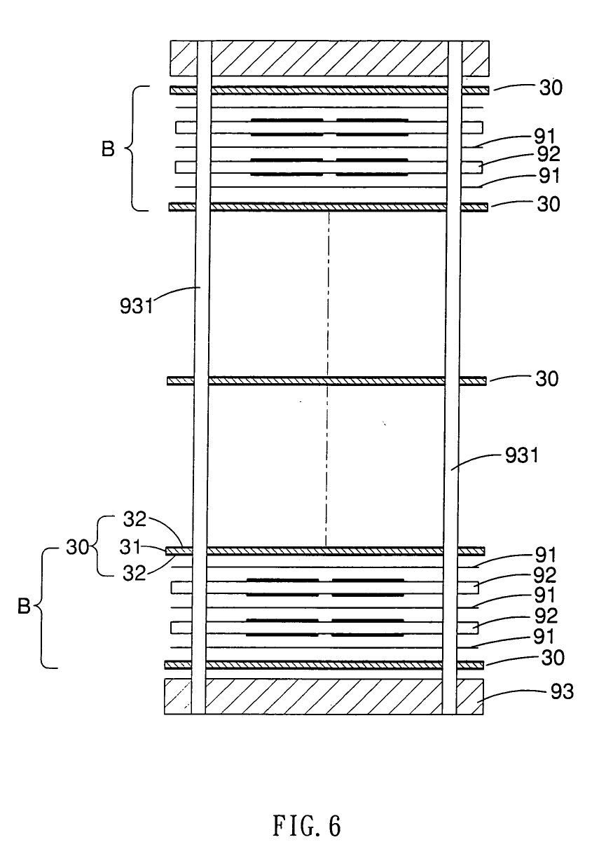

Referring to the drawings and initially to FIGS. 2 and 6, a pin lamination method that may eliminate pits and dents formed in a multi-layer printed wiring board in accordance with a preferred embodiment of the present invention comprises the steps described as follows.

In the first step, a plurality of steel plates 31 and coppers 32 are prepared in a clean working room “S1”, and a plurality of prepregs 91 and cores 92 are prepared in a working room “S2”. Each of the steel plates 31, the coppers 32, the prepregs 91 and the cores 92 are pre-fabricated with multiple pin holes “H”.

In the second step, a ply-up device 80 is provided in the clean working room “S1”. The ply-up device 80 is provided with multiple pins 822.

A copper 32 having a shiny surface facing upward, a steel plate 31, and a copper 32 having a shiny surface facing downward are laminated on the ply-up device 80 serially, thereby forming a sandwiched lamination board 30, with the steel plate 31 sandwiched between the two coppers 32, wherein the shiny surface of each of the two coppers 32 is directed toward the steel plate 31.

Thus, the sandwiched lamination board 30 is made in the clean working room “S1”, so that powder and dust will not stick on the surface of the sandwiched lamination board 30.

Preferably, the pin holes “H” of the copper 32 and the steel plate 31 align with the pins 822 of the ply-up device 80, thereby facilitating insertion of the pins 822 of the ply-up device 80.

In the third step, the sandwiched lamination board 30 is conveyed to the working room “S2”. Two mold plates 93 are provided in the working room “S2”. Each of the mold plates 93 is provided with multiple pins 931. The sandwiched lamination board 30 may be laminated with multiple prepregs 91, and multiple cores 92 serially, thereby forming a multi-layer board “B”. Thus, multiple multi-layer boards “B” may be mounted between the two mold plates 93 as shown in FIG. 6.

Preferably, the pin holes “H” of the sandwiched lamination board 30, the prepregs 91, and the cores 92 align with the pins 931 of the mold plates 93, thereby facilitating insertion of the pins 931 of the mold plates 93.

Finally, the multiple multi-layer boards “B” mounted between the two mold plates 93 as shown in FIG. 6 may be treated by a heat press process, thereby making multiple finished multi-layer boards “B”. Then, the copper 32 at the outer layer of each of the finished multi-layer boards “B” may be printed with circuit patterns, thereby making the multi-layer printed wiring board.

In practice, a partition wall 7 is mounted between the clean working room “S1” and the working room “S2”, and is formed with a passage 71, so that the sandwiched lamination board 30 may be conveyed from the clean working room “S1” to the working room “S2” by a conveyor belt 6.

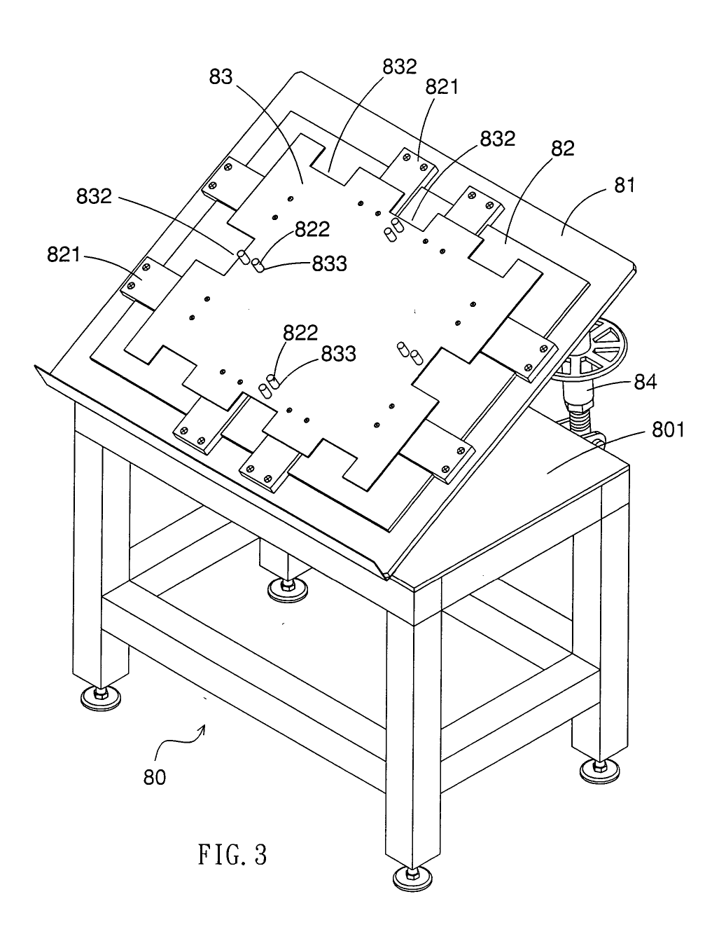

Referring to FIGS. 3-5 with reference to FIGS. 2 and 6, the ply-up device 80 in the second step includes a work table 801, a lift rod 84, an inclined board 81, a base steel plate 81, and a ply-up plate 83.

The lift rod 84 has a first end pivoted on a first side of the work table 801, and a second end pivoted with a first end of the inclined board 81 which has a second end pivoted on a second side of the work table 801. The lift rod 84 may be lifted and lowered for adjusting the inclined angle of the inclined board 81.

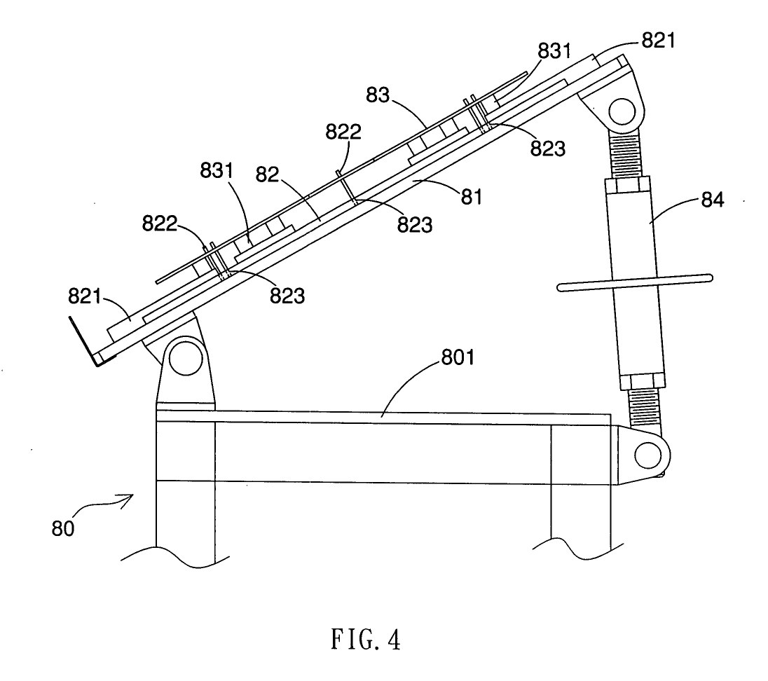

The base steel plate 82 includes multiple L-shaped fixing blocks 821 secured on the inclined board 81, and is provided with multiple pin holes 823 (FIG. 4) for insertion of multiple pins 822.

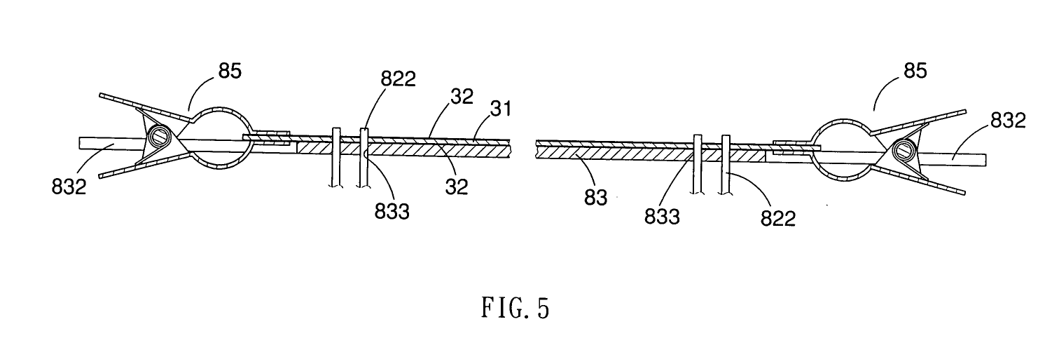

The ply-up plate 83 includes multiple pads 831 secured on the fixing blocks 821, and is provided with multiple pin holes 833 for insertion of the multiple pins 822. The ply-up plate 83 has a periphery formed with multiple openings 832 for insertion of holders 85 (FIG. 5).

Thus, in the second step, a first copper 32 having a shiny surface facing upward is mounted on the ply-up plate 83, with the pin holes “H” of the first copper 32 aligning with the pins 822 of the ply-up plate 83 of the ply-up device 80 for insertion of the pins 822 of the ply-up plate 83 of the ply-up device 80. Then, a steel plate 31 is mounted on the first copper 31, with the pin holes “H” of the steel plate 31 aligning with the pins 822 of the ply-up plate 83 of the ply-up device 80 for insertion of the pins 822 of the ply-up plate 83 of the ply-up device 80. Then, a second copper 32 having a shiny surface facing downward is mounted on the steel plate 31, with the pin holes “H” of the second copper 32 aligning with the pins 822 of the ply-up plate 83 of the ply-up device 80 for insertion of the pins 822 of the ply-up plate 83 of the ply-up device 80. Thus, the first copper 32, the steel plate 31 and the second copper 32 may be laminated on the ply-up plate 83 of the ply-up device 80 serially, thereby forming a sandwiched lamination board 30 with the steel plate 31 sandwiched between the two coppers 32, wherein the shiny surface of each of the two coppers 32 is directed toward the steel plate 31. Finally, the holders 85 may be extended into the openings 832 of the ply-up plate 83 to clamp and secure the sandwiched lamination board 30 as shown in FIG. 5.

As shown in FIGS. 2 and 6, in the third step, multiple sandwiched lamination boards 30 may be conveyed to the working room “S2”. Then, the sandwiched lamination board 30 may be laminated with multiple prepregs 91, and multiple cores 92 serially, thereby forming a multi-layer board “B”. Then, the holders 85 may be removed. Thus, multiple multi-layer boards “B” may be mounted between the two mold plates 93 as shown in FIG. 6. The pin holes “H” of the sandwiched lamination board 30, the prepregs 91, and the cores 92 align with the pins 931 of the mold plates 93, thereby facilitating insertion of the pins 931 of the mold plates 93. Then, the multiple multi-layer boards “B” mounted between the two mold plates 93 as shown in FIG. 6 may be treated by a heat press process, thereby making multiple finished multi-layer boards “B”. Then, the copper 32 at the outer layer of each of the finished multi-layer boards “B” may be printed with circuit patterns, thereby making the multi-layer printed wiring board.

According to the pin lamination method that may eliminate pits and dents formed in a multi-layer printed wiring board and the ply-up device thereof in accordance with a preferred embodiment of the present invention, the steel plate 31 is sandwiched between the two coppers 32, thereby forming the sandwiched lamination board 30 which is made in the clean working room “S1”, wherein the shiny surface of each of the two coppers 32 is directed toward the steel plate 31, so that powder and dust will not stick on the surface of the sandwiched lamination board 30.

Thus, the steel plate 31 is sandwiched between the two coppers 32, without a possibility of being adhered with powder and dust, and the shiny surface of each of the two coppers 32 is directed toward the steel plate 31, without a possibility of being adhered with powder and dust, so that the finished multi-layer board “B” will eliminate pits and dents, thereby enhancing the quality of the multi-layer board “B”, and thereby enhancing the quality of the product of the multi-layer printed wiring board.

Although the invention has been explained in relation to its preferred embodiment as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. A pin lamination method that may eliminate pits and dents formed in a multi-layer printed wiring board, comprising the steps of:
(a) preparing a plurality of steel plates and coppers in a clean working room, and a plurality of prepregs and cores in a working room;
(b) serially laminating a first one of the coppers having a shiny surface facing upward, one of the steel plates, and a second one of the coppers having a shiny surface facing downward on a ply-up device, thereby forming a sandwiched lamination board, with the steel plate sandwiched between the first and second coppers, wherein the shiny surface of each of the first and second coppers is directed toward the steel plate; and
(c) conveying the sandwiched lamination board to the working room, and laminating the sandwiched lamination board, the prepregs, and the cores serially, thereby forming a multi-layer board.

2. The pin lamination method that may eliminate pits and dents formed in a multi-layer printed wiring board in accordance with claim 1, wherein in the step (a), each of the steel plates, the coppers, the prepregs, and the cores are pre-fabricated with multiple pin holes.

3. The pin lamination method that may eliminate pits and dents formed in a multi-layer printed wiring board in accordance with claim 2, wherein in the step (b), the ply-up device is provided with multiple pins, and the pin holes of the coppers and the steel plate align with the pins of the ply-up device, thereby facilitating insertion of the pins of the ply-up device.

4. The pin lamination method that may eliminate pits and dents formed in a multi-layer printed wiring board in accordance with claim 1, wherein in the step (c), the sandwiched lamination board, the prepregs, and the cores are mounted between two mold plates provided in the working room.

5. The pin lamination method that may eliminate pits and dents formed in a multi-layer printed wiring board in accordance with claim 4, wherein each of the two mold plates is provided with multiple pins, and pin holes of the sandwiched lamination board, the prepregs, and the cores align with the pins of the mold plates, thereby facilitating insertion of the pins of the mold plates.

6. A ply-up device for performing the pin lamination method that may eliminate pits and dents formed in a multi-layer printed wiring board in accordance with claim 1, wherein the ply-up device includes a work table, a lift rod, an inclined board, a base steel plate, and a ply-up plate, wherein:
the lift rod has a first end pivoted on a first side of the work table, and a second end pivoted with a first end of the inclined board which has a second end pivoted on a second side of the work table, the lift rod may be lifted and lowered for adjusting the inclined angle of the inclined board;
the base steel plate is secured on the inclined board; and
the ply-up plate is secured on the base steel plate.

7. The ply-up device in accordance with claim 6, wherein the base steel plate includes multiple L-shaped fixing blocks secured on the inclined board, and is provided with multiple pin holes for insertion of multiple pins.

8. The ply-up device in accordance with claim 7, wherein the ply-up plate includes multiple pads secured on the fixing blocks, and is provided with multiple pin holes for insertion of the multiple pins.

9. The ply-up device in accordance with claim 6, wherein the ply-up plate has a periphery formed with multiple openings for insertion of holders.
